(19) United States
(12) Patent Application Publication
(10) Pub. No.: US 2001/0015922 A1
(43) Pub. Date: Aug. 23, 2001

(54) Semiconductor device with an integrated CMOS circuit with MOS transistors having silicon-germanium (Si1-xGex) gate electrodes, and method of manufacturing same

(75) Inventor: Youri Ponomarev, Eindhoven (NL)

Correspondence Address: Michael E. Marion, Corporate Patent Counsel, U.S. Philips Corporation, 580 White Plains Road, Tarrytown, NY, 10591, US

(73) Assignee: PHILIPS CORPORATION

(21) Appl. No.: 09/784,424

(22) Filed: Feb. 15, 2001

(30) Foreign Application Priority Data
Feb. 17, 2000 (EP) 00200540.3
Mar. 21, 2000 (EP) 00201028.8

(51) Int. Cl. G11C 29/00

(52) U.S. Cl. 365/200

(57) ABSTRACT

Semiconductor device comprising an integrated CMOS circuit with NMOS and PMOS transistors (A, B) having semiconductor zones (23, 24, 29, 30) formed in a silicon substrate (1). At the locations of the gate zones (29, 30), the surface (3) of the substrate is provided with a layer of gate oxide (11) on which gate electrodes (16, 17) are formed. The gate electrodes (17) of the PMOS transistors (B) are formed in a layer of p-type doped polycrystalline silicon (14) and a layer of p-type doped polycrystalline silicon-germanium(13) (Si₁₋ₓGeₓ; 0<x<1) sandwiched between the silicon-germanium layer and the gate oxide. The gate electrodes (16) of the NMOS transistors (A) are formed in a layer of n-type doped polycrystalline silicon (14) without germanium. The integrated CMOS circuit combines advantages of PMOS transistors having p-type doped silicon-germanium gate electrodes with advantages of NMOS transistors having n-type doped silicon gate electrodes.

The invention relates to a semiconductor device with an integrated CMOS circuit with NMOS and PMOS transistors having semiconductor zones which are formed in a silicon substrate and which adjoin a surface thereof, which surface is provided with a layer of gate oxide on which gate electrodes are formed at those areas of the semiconductor zones which form gate zones of these transistors, such that the gate electrodes of the PMOS transistors are formed in a layer of p-type doped polycrystalline silicon and a layer of p-type doped polycrystalline silicon-germanium (Si₁₋ₓGeₓ; 0<x<1) situated between said polycrystalline silicon layer and the gate oxide.

The layer of silicon-germanium (Si₁₋ₓGeₓ) may be deposited in a usual manner by means of a CVD (Chemical Vapor Deposition) process from a gas mixture comprising silane (SiH₄), germanium hydride (GeH₄), and nitrogen. The fraction x is determined here by the ratio of the quantities of silane and germanium hydride in the gas mixture. Layers can be deposited in practice on gate oxide for which the fraction x may lie between 0 and 1.

A semiconductor device of the kind mentioned in the opening paragraph is known from EP-A-614226 in which not only the gate electrodes of the PMOS transistors but also those of the NMOS transistors are formed in a layer of polycrystalline silicon and a layer of polycrystalline silicon-germanium (Si₁₋ₓGeₓ) situated between the former layer and the gate oxide. The gate electrodes further comprise a top layer of a metal silicide provided on the layer of polycrystalline silicon. The gate electrodes of the PMOS transistors are p-type doped, those of the NMOS transistors n-type doped.

NMOS and PMOS transistors for use in integrated CMOS circuits are designed in practice such that they have equal threshold voltages Vₜ, in absolute value; the threshold voltage for transistors of the “0.18 μm generation”, for example, has a target value of 0.3 V. When a p-type doped gate electrode of polycrystalline silicon in a PMOS transistor is replaced by a p-type doped gate electrode of polycrystalline silicon-germanium, the threshold voltage of the transistor will become higher. The doping level of the gate zone of the transistor can be reduced so as to obtain nevertheless a transistor having the desired, lower threshold voltage. In a “0.18 μm generation” PMOS transistor with a threshold voltage of 0.3 V, for example, the addition of 30 at % of germanium renders it possible to reduce the doping with a surface concentration of 5.10¹⁷ to a doping with a surface concentration of 3.10¹⁷. Such a lower doping level of the gate zone has advantages. The transistor will have a higher Iₒₙ, a lower I_{off}, and thus a higher Iₒₙ/I_{off} ratio. It is also found then that the influence of the substrate voltage on the threshold voltage Vₜ is smaller. These advantages are greater in proportion as the quantity of germanium in the silicon-germanium layer is greater, and thus the doping level of the gate zone is lower. This is not true for NMOS transistors. Indeed, NMOS transistors with n-type doped silicon-germanium gate electrodes have worse characteristics than NMOS transistors with n-type doped silicon gate electrodes without germanium, in particular if the quantity of germanium in the silicon-germanium layer is more than 30 at %. Since the characteristics of PMOS transistors are improved especially when more than 30 at % of germanium is added to the gate electrode, such an addition to gate electrodes of complementary PMOS and NMOS transistors, as in the known semiconductor device described, would not seem to be very useful.

The invention has for its object inter alia to provide a solution to the above problem, which does render it useful to use gate electrodes with a layer of polycrystalline silicon-germanium adjoining the gate oxide in an integrated CMOS circuit. The semiconductor device mentioned in the opening paragraph is for this purpose characterized in that the gate electrodes of the NMOS transistors are formed in a layer of n-type doped polycrystalline silicon without germanium.

The use of p-type doped gate electrodes formed in a layer of polycrystalline silicon and a layer of doped polycrystalline silicon-germanium (Si₁₋ₓGeₓ) interposed between the former layer and the gate oxide in PMOS transistors has the advantages mentioned above. The use of n-type silicon-germanium gate electrodes in NMOS transistors has only disadvantages. n-type dopants such as arsenic and phosphorus added to silicon-germanium gate electrodes are difficult to activate and are easily deactivated again through heating during treatments carried out subsequently in the manufacturing process at elevated temperatures. These non-activated atoms of the dopant give rise to an undesirably strong depletion of the gate zone.

The measure according to the invention renders it possible to form integrated circuits with complementary NMOS and PMOS transistors which have better characteristics than integrated circuits with complementary NMOS and PMOS transistors which are all provided with silicon-germanium gate electrodes, but also than integrated circuits with complementary NMOS and PMOS transistors which are all provided with silicon gate electrodes without germanium. The advantages of the use of silicon-germanium gate electrodes in PMOS transistors are utilized, while the disadvantages of the use of such gate electrodes in NMOS transistors are avoided.

The advantages mentioned above are greatest when the layer of p-type doped polycrystalline silicon-germanium (Si₁₋ₓGeₓ) contains more than 30 at % of germanium (x>0.3). If such layers are deposited on a layer of amorphous silicon which is less than 5 nm thick, layers will be formed with a low surface roughness, while the operation of the transistors mentioned above is not affected.

A preferred embodiment of the semiconductor device comprises besides said PMOS transistors also PMOS transistors having gate electrodes which are formed in a layer of p-type doped polycrystalline silicon without germanium situated on the gate oxide, the latter PMOS transistors being equal to the former in all other respects. These PMOS transistors, which have a gate zone with the same doping as the PMOS transistors with the silicon-germanium gate electrodes, show a lower threshold voltage. Given the gate zone doping level mentioned above by way of example, with a surface concentration of 3.10¹⁷ atoms per cc, the threshold voltage is only −0.1 V instead of −0.3 V. These transistors, which can be added to the integrated circuit in a simple manner, as will become apparent below, are more suitable, for example, for amplifying analog signals than the transistors with a higher threshold voltage.

The invention also relates to a method of manufacturing a semiconductor device with an integrated CMOS circuit with NMOS and PMOS transistors having semiconductor zones which are formed in a silicon substrate and which adjoin a surface thereof, which surface is provided with a layer of gate oxide on which silicon-germanium gate electrodes are formed for the PMOS transistors and silicon gate electrodes without germanium are formed for the NMOS transistors. The gate electrodes are formed in this method in that, in that order, a layer of polycrystalline silicon germanium is deposited on the gate oxide layer, a photoresist mask is formed on the layer of polycrystalline silicon-germanium which covers said layer at the areas of PMOS transistors and does not cover it at the areas of NMOS transistors, an etching treatment is carried out whereby the layer of silicon germanium is removed from the gate oxide layer at the areas of said NMOS transistors, the photoresist mask is removed, a layer of polycrystalline silicon is deposited on the structure thus formed, a gate electrode is formed at the areas of said PMOS transistors in the layer of polycrystalline silicon-germanium and the covering layer of polycrystalline silicon present there, and a gate electrode is formed at the areas of said NMOS transistors in the layer of polycrystalline silicon present there. The semiconductor zones which form the sources and drains of the transistors are formed in a usual manner through ion implantation, the gate electrodes previously formed serving as a mask. The gate electrodes of the PMOS transistors are automatically strongly p-type doped and the gate electrodes of the NMOS transistors strongly n-type doped thereby.

A photoresist mask is provided, covering the surface at the areas of NMOS transistors and leaving it exposed at the areas of the PMOS transistors, during the formation of the active regions in which the PMOS transistors are formed. A photoresist is provided, covering the surface at the areas of the PMOS transistors and leaving it exposed at the areas of the NMOS transistors, during the formation of the active regions in which the NMOS transistors are formed. The second photoresist mask may at the same time be used as the photoresist mask which, in the method according to the invention, does cover the layer of silicon-germanium at the areas of the PMOS transistors and does not cover it at the areas of the NMOS transistors, and which is used for removing the layer of silicon-germanium at the areas of said NMOS transistors from the layer of gate oxide. These two, identical photoresist masks may be formed by means of one and the same photolithographic mask.

Preferably, a layer of polycrystalline silicon-germanium (Si₁₋ₓGeₓ) containing more than 30 at % of germanium (x>0.3) is deposited on the gate oxide layer. A layer with a smooth surface is formed thereby if first a layer of amorphous silicon less than 5 nm thick is formed on the gate oxide layer before the layer of silicon-germanium is deposited thereon.

Besides the PMOS transistors with silicon-germanium gate electrodes and NMOS transistors with silicon gate electrodes, PMOS transistors with silicon gate electrodes without germanium can also be formed in a simple manner without additional photoresist masks being necessary for this. Gate electrodes may then be formed in the layer of polycrystalline silicon, in which also the gate electrodes of the NMOS transistors are formed, at the areas of these PMOS transistors. The gate electrodes are formed by means of a photoresist mask with which also the gate electrodes of NMOS transistors are formed. The sources and drains are formed by means of the photoresist mask which also serves to form the sources and drains of the other PMOS transistors. To realize this alternative design, it suffices to adapt the photolithographic masks necessary for the manufacture of said photoresist masks to this different design.

The invention will be explained in more detail below by way of example with reference to a drawing, in which:

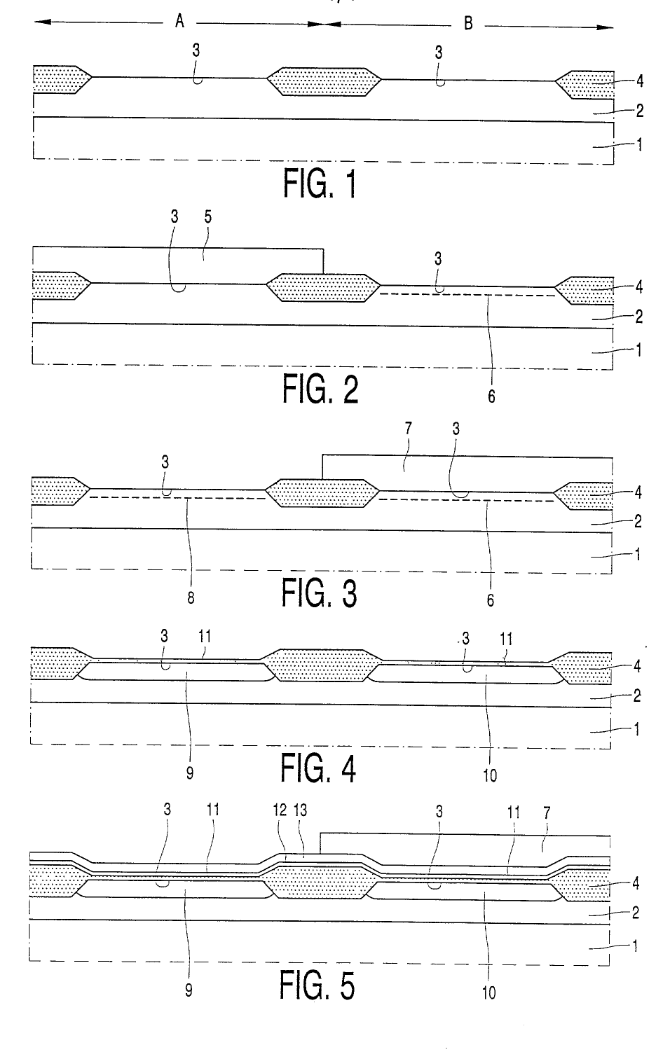

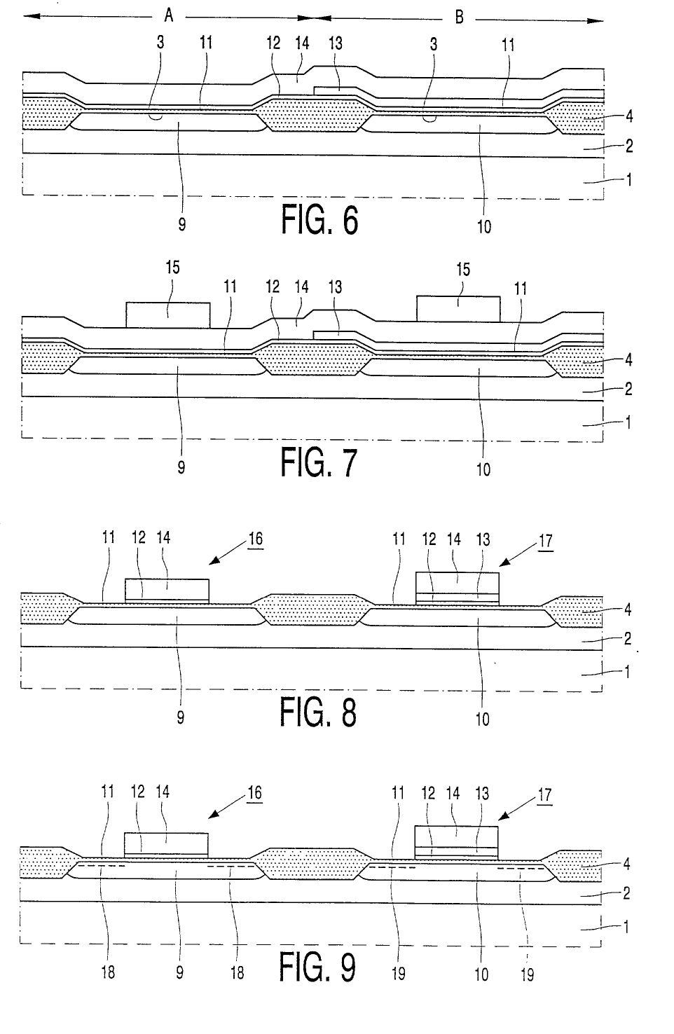

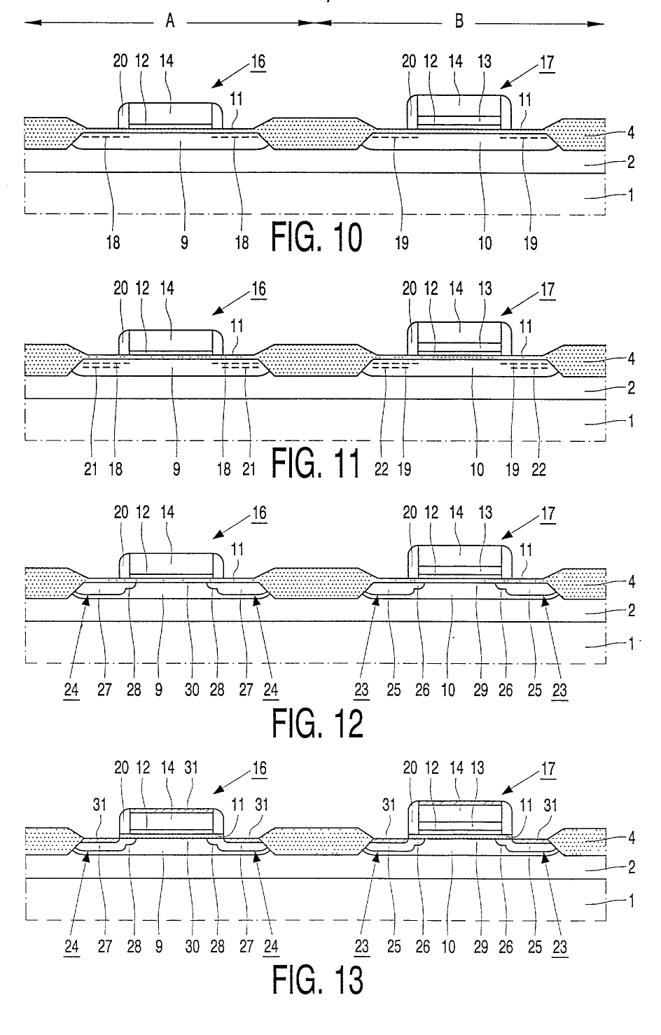

FIGS. 1 to 13 diagrammatically and in cross-section show a number of stages in the manufacture of a semiconductor device with an integrated CMOS circuit according to the invention, and

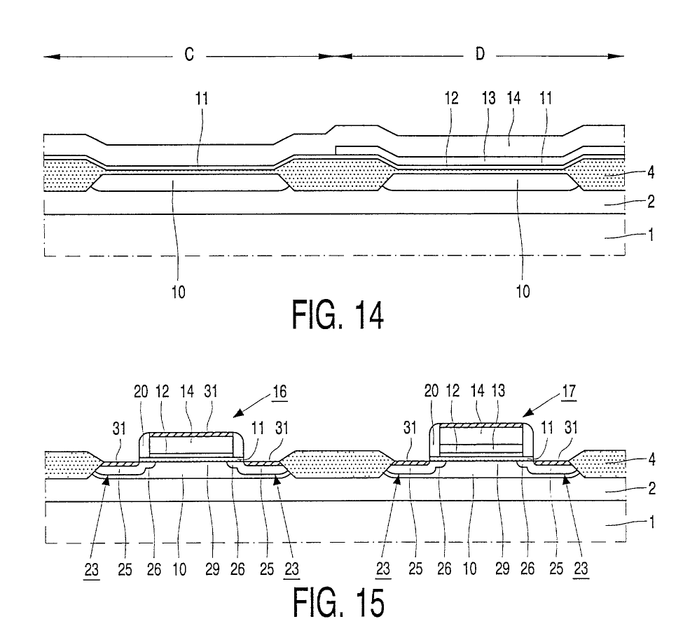

FIGS. 14 and 15 diagrammatically and in cross-section show a few stages in the manufacture of a preferred embodiment of a semiconductor device with an integrated CMOS circuit according to the invention.

FIGS. 1 to 13 diagrammatically and in cross-section show a number of stages in the manufacture of a semiconductor device with an integrated CMOS circuit with NMOS and PMOS transistors. The Figures show the manufacture of only a single NMOS and a single PMOS transistor for the sake of clarity. It will be obvious that an integrated circuit may comprise very many such transistors.

The starting point is a silicon wafer 1 which is provided with an approximately 3 μm thick epitaxially grown top layer 2 which is lightly p-type doped in this example with approximately 3.10¹⁵ atoms per cc. In a usual manner, active regions A and B are formed in the top layer 2, which regions adjoin a surface 3 and are insulated from one another by field oxide regions 4. The field oxide regions 4 are formed here through local oxidation of silicon, but they may alternatively be formed, for example, through etching of grooves in the surface 3 which are then filled with an insulating material. NMOS transistors are formed in the active regions A, and PMOS transistors in the active regions B.

After the formation of the field oxide regions, a first photoresist mask 5 is provided which covers the active regions A for the NMOS transistors and leaves the active regions B for the PMOS transistors exposed, whereupon phosphorus ions are implanted, as indicated with a broken line 6. The photoresist mask 5 is then removed and a second photoresist mask 7 is provided which covers the active regions B for the PMOS transistors and leaves the active regions A for the NMOS transistors exposed, whereupon boron ions are implanted, as indicated with a broken line 8. The photoresist mask 7 is removed and a heat treatment is subsequently carried out, such that p-type doped regions 9 adjoining the surface 3, referred to as p-wells, are formed in the active regions A, and n-type doped regions 10 adjoining the surface 3, referred to as n-wells, are formed in the active regions B. The regions 9 and 10 are approximately 600 nm deep and are all lightly doped with approximately 2.10¹⁷ atoms per cc, the doping showing a higher concentration of approximately 3.10¹⁷ atoms per cc at the surface 3. An approximately 5 nm thick layer of gate oxide 11 is also formed on the surface 3 at the areas of the active regions A and B in a usual manner by thermal oxidation of silicon.

After the p-well 9, the n-well 10, and the gate oxide layer 111 have been formed, an approximately 2 nm thick layer of amorphous silicon 12 and an approximately 20 nm thick layer of polycrystalline silicon-germanium (Si₁₋ₓGeₓ) 13 are deposited. The silicon-germanium layer 13 is deposited in a usual CVD process from a gas mixture comprising silane (SiH₄), germanium hydride (GeH₄) and nitrogen as a carrier gas. The germanium fraction in the silicon-germanium layer follows from the ratio of silane to germanium hydride in the gas mixture. The layer 13 may contain up to 100 at % germanium. In this example, a layer is deposited which contains 30 at % germanium. The deposition of the silicon-germanium layer 13 on the layer of amorphous silicon 12 has the advantage that a silicon-germanium layer is formed which has a smoother surface than if the layer of silicon-germanium were directly deposited on the gate oxide 11, but the layer of amorphous silicon 12 is not essential to the invention.

Subsequently, the second photoresist mask 7, which leaves the active regions A for the NMOS transistors exposed and covers the active regions B for the PMOS transistors, is provided again. The silicon-germanium layer 10 is etched away from the layer of amorphous silicon at the areas of the active regions in an etching bath with nitric acid and hydrofluoric acid (30 vol % HNO₃, 20 vol % H₂O, and 10 vol % dilute HF [0.08% HF]). The second photoresist mask 7 was previously used for forming the p-well 9. An identical photolithographic mask is used for forming the photoresist mask 7 a second time.

After the second photoresist mask 7 has been removed, an approximately 120 μm thick layer of polycrystalline silicon 14 is deposited in a usual manner. A photoresist mask 15 is formed on this layer of polycrystalline silicon 14 for defining the gate electrodes of the transistors. The gate electrodes 16 of the NMOS transistors and the gate electrodes 17 of the PMOS transistors are etched into the layers in a usual etching plasma. The gate electrodes 17 of the PMOS transistors are formed in the layer of polycrystalline silicon 14, in the subjacent layer of silicon-germanium 13, and in the layer of amorphous silicon 12, the gate electrodes 16 of the NMOS transistors only in the layer of polycrystalline silicon 14 and the layer of amorphous silicon 12. The gate electrodes 16 and 17 in this example have a width of 0.18 μm.

The sources and drains of the transistors are then formed. First a photoresist mask is provided which covers the regions B and exposes the regions A, whereupon arsenic ions are implanted, indicated with a broken line 18 in FIG. 9. After this photoresist mask has been removed, a photoresist mask is provided which exposes the regions B and covers the regions A, whereupon boron ions are implanted, indicated with a broken line 19 also in FIG. 9. The gate electrodes 16 and 17 are provided with spacers 20 of silicon oxide in a usual manner after the removal of the photoresist mask, i.e. an approximately 150 nm thick layer of silicon oxide is deposited and is subsequently subjected to an anisotropic etching treatment until the gate electrodes 16 and 17 have become exposed again at their upper sides. Then a photoresist mask (not shown) which covers the regions 5 and exposes the regions A is provided, after which arsenic ions are once more implanted, indicated with broken line 21. After this photoresist mask 11 has been removed, a photoresist mask (not shown) is provided which exposes the regions B and covers the regions A, whereupon boron ions are once more implanted, indicated with a broken line 22. After this final photoresist mask has been removed, a heat treatment is carried out whereby the source and drain zones 23, 24 of the transistors are formed. The source and drain zones 23 of the PMOS transistors are p-type doped with a portion 25 doped with approximately 10 atoms per cc and a portion 26 doped with approximately 10²⁰ atoms per cc which extends to below the gate electrode 17. The source and drain zones 24 of the NMOS transistors are n-type doped with a portion 27 doped with approximately 10²¹ atoms per cc and a portion 28 doped with approximately 10-20 atoms per cc which extends to below the gate electrode 16. The portion 29 of the n-well 10 situated between the source and the drain zones 23 forms the gate zone of the PMOS transistor, the portion 30 of the p-well 9 situated between the source and drain zones 24 forms the gate zone of the NMOS transistor. While the source and drain zones 23 and 24 are being formed by ion implantation and a heat treatment, the gate electrodes are at the same time provided with a doping; the gate electrodes 17 of the PMOS transistors with a p-type doping and the gate electrodes 16 of the NMOS transistors with an n-type doping. Finally, the gate oxide is etched away adjacent the gate electrodes 16 and 17, and the gate electrodes 16 and 17 and the source and drain zones 23 and 24 are provided with a top layer 31 of titanium disilicide (TiSi₂) in a usual, self-aligned manner.

A semiconductor device has thus been created, with NMOS and PMOS transistors with semiconductor zones 23, 24, 29, 30 formed in a silicon substrate 1 and adjoining a surface 3 thereof, which surface 3 is provided with a gate oxide layer 11 at the areas of the semiconductor zones forming the gate zones 29, 30 of these transistors, on which gate oxide layer gate electrodes 16 and 17 are formed, such that the gate electrodes 17 of the PMOS transistors are formed in a p-type doped polycrystalline silicon layer 14 and a p-type doped polycrystalline silicon-germanium (Si₁₋ₓGeₓ) layer 13 sandwiched between said layer 14 and the gate oxide 11, and the gate electrodes 16 of the NMOS transistors are formed in a layer of n-type doped polycrystalline silicon 14 without germanium lying on the gate oxide 11.

The PMOS transistors with silicon-gernanium gate electrodes 17 with 30 at % germanium and gate zones having a doping with a surface concentration of 3.10¹⁷ atoms per cc as formed in the present example have the same threshold voltage of −0.3 V, an approximately 10% higher Iₒₙ, and an approximately 10% lower I_{off} than a PMOS transistor with a silicon gate electrode without germanium and a gate zone with a surface doping concentration of 5.10¹⁷ atoms per cc which is identical in all other respects. These more favorable properties result from the lighter doping of the gate zone of the transistor. They may be even better as more germanium is incorporated in the silicon-germanium layer. If this quantity is, for example, 60 at % (x=0.6), the doping of the gate zone can be reduced to a surface concentration of approximately 1.10¹⁷ atoms per cc in order to realize the same Vₜ of −0.3 V, whereby an approximately 25% higher Iₒₙ, and an approximately 15% lower I_{off} are realized compared with said transistor having a silicon gate electrode without germanium. Preferably, therefore, a layer of p-type doped polycrystalline silicon-germanium (Si₁₋ₓGeₓ) is used which comprises more than 30 at % germanium (x>0.3).

Such advantages cannot be achieved in the NMOS transistors with the use of a silicon-germanium gate electrode. The n-type dopant in the gate electrodes of silicon-germanium cannot be well activated; the relevant non-activated atoms cause an undesirably strong depletion of the gate zone. When silicon-germanium gate electrodes are used for PMOS transistors but not for NMOS transistors, the advantages of the former are utilized and the disadvantages of the latter are avoided.

FIGS. 14 and 15 diagrammatically and in cross-section show a few stages in the manufacture of a preferred embodiment of a semiconductor device with an integrated CMOS circuit. PMOS transistors with silicon gate electrodes without germanium are formed besides the PMOS transistors with silicon-germanium gate electrodes 17 formed in the regions B and the NMOS transistors with silicon gate electrodes 16 formed in the regions A, without additional photoresist masks being necessary. Active regions C are formed for this purpose in addition to the active regions A and B. As FIG. 14 shows, the regions C are provided with n-wells 10, as was the case for the regions B. The silicon-germanium layer 13 is removed from the layer of amorphous silicon 12 in the regions C, as in the regions A, and the layer of polycrystalline silicon 14 is directly deposited on the layer of amorphous silicon 12. As FIG. 15 shows, the same gate electrodes 16 are formed on the gate oxide layer 11 in the regions C as in the regions A, and source and drain zones 23 are formed as in the regions B. The PMOS transistors thus formed in the regions B and C differ only in the shapes of their respective gate electrodes 16 and 17, they are identical in all other respects. The gate electrodes 16 of the PMOS transistors in the regions C are formed by means of a photoresist mask with which also the gate electrodes 16 of the NMOS transistors are formed in the regions A. The sources and drains of the PMOS transistors in the regions C are formed by means of the photoresist mask with which also the sources and drains of the PMOS transistors are formed in the regions B. To realize this alternative design, it suffices to adapt the photolithographic masks necessary for manufacturing these photoresist masks so as to comply with this new design.

The PMOS transistors with the silicon gate electrodes 16 formed in the regions C have gate zones 29 with the same doping as the PMOS transistors with the silicon-germanium gate electrodes 17 formed in the regions B, and accordingly show a lower threshold voltage. Given the gate zone doping with a surface concentration of 3.10¹⁷ atoms per cc mentioned here by way of example, the threshold voltage will be no more than −0.1 V instead of −0.3 V. Such transistors are more suitable, for example, for amplifying analog signals than the transistors having higher threshold voltages.

1. A semiconductor device with an integrated CMOS circuit with NMOS and PMOS transistors having semiconductor zones which are formed in a silicon substrate and which adjoin a surface thereof, which surface is provided with a layer of gate oxide on which gate electrodes are formed at those areas of the semiconductor zones which form gate zones of these transistors, such that the gate electrodes of the PMOS transistors are formed in a layer of p-type doped polycrystalline silicon and a layer of p-type doped polycrystalline silicon-germanium (Si₁₋ₓGeₓ; 0<x<1) situated between said polycrystalline silicon layer and the gate oxide, characterized in that the gate electrodes of the NMOS transistors are formed in a layer of n-type doped polycrystalline silicon without germanium.

2. A semiconductor device as claimed in claim 1, characterized in that the layer of p-type doped polycrystalline silicon-germanium (Si₁₋ₓGeₓ) contains more than 30 at % of germanium (x>0.3).

3. A semiconductor device as claimed in claim 1 or 2, characterized in that a less than 5 nm thick layer of amorphous silicon is formed between the gate oxide layer and the layer of polycrystalline silicon-germanium.

4. A semiconductor device as claimed in claim 2 or 3, characterized in that the semiconductor device comprises besides said PMOS transistors also PMOS transistors having gate electrodes which are formed in a layer of p-type doped polycrystalline silicon without germanium situated on the gate oxide, the latter PMOS transistors being equal to the former in all other respects.

5. A method of manufacturing a semiconductor device with an integrated CMOS circuit with NMOS and PMOS transistors having semiconductor zones which are formed in a silicon substrate and which adjoin a surface thereof, which surface is provided with a layer of gate oxide on which silicon-germanium gate electrodes are formed for the PMOS transistors and silicon gate electrodes without germanium are formed for the NMOS transistors, characterized in that the gate electrodes are formed in this method in that, in that order,
a layer of polycrystalline silicon germanium (Si₁₋ₓGeₓ; 0<x<1) is deposited on the gate oxide layer,
a photoresist mask is formed on the layer of polycrystalline silicon-germanium which covers said layer at the areas of PMOS transistors and does not cover it at the areas of NMOS transistors,
an etching treatment is carried out whereby the layer of silicon-germanium is removed from the gate oxide layer at the areas of said NMOS transistors,
the photoresist mask is removed,
a layer of polycrystalline silicon is deposited on the structure thus formed, and
a gate electrode is formed at the areas of said PMOS transistors in the layer of polycrystalline silicon-germanium and the covering layer of polycrystalline silicon present there, and a gate electrode is formed at the areas of said NMOS transistors in the layer of polycrystalline silicon present there.

6. A method as claimed in claim 5, characterized in that a layer of polycrystalline silicon-germanium (Si₁₋ₓGeₓ) containing more than 30 at % of germanium (x>0.3) is deposited on the gate oxide layer.

7. A method as claimed in claim 5 or 6, characterized in that first a layer of amorphous silicon less than 5 nm thick is formed on the gate oxide layer before the layer of silicon-germanium is deposited thereon.

8. A method as claimed in claim 5, 6, or 7, characterized in that gate electrodes are formed in the layer of polycrystalline silicon, in which also the gate electrodes of the NMOS transistors are formed, for the creation of PMOS transistors with silicon gate electrodes without germanium at areas reserved for these PMOS transistors.
